(19) United States
(12) Patent Application Publication
(10) Pub. No.: US 2022/0201236 A1
(43) Pub. Date: Jun. 23, 2022

(54) OPTICAL SENSOR WITH SIMULTANEOUS IMAGE/VIDEO AND EVENT DRIVEN SENSING CAPABILITIES

(71) Applicant: OMNIVISION TECHNOLOGIES, INC., Santa Clara, CA (US)

(72) Inventors: Zhe Gao, San Jose, CA (US); Tiejun Dai, Santa Clara, CA (US); Ling Fu, Santa Clara, CA (US); Qing Qin, Santa Clara, CA (US); Andreas Suess, San Jose, CA (US)

(21) Appl. No.: 17/125,630

(22) Filed: Dec. 17, 2020

(51) Int. Cl. H04N 5/3745; H01L 27/146

(52) U.S. Cl. CPC H04N 5/37455; H01L 27/14612; H01L 27/1463

(57) ABSTRACT

An optical sensor includes a pixel array of pixel cells. Each pixel cell includes photodiodes to photogenerate charge in response to incident light and a source follower to generate an image data signal in response to the charge photogenerated from the photodiodes. An image readout circuit is coupled to the pixel cells to read out the image data signal generated from the source follower of at least one of the pixel cells of a row of the pixel array. An event driven circuit is coupled to the pixel cells to read out the event data signals generated in response to the charge from the photodiodes of another row of the pixel cells of the pixel array. The image readout circuit is coupled to read out the image data signal and the event driven circuit is coupled to read out the event data signals from pixel array simultaneously.

### BACKGROUND INFORMATION

### Field of the Disclosure

This disclosure relates generally to image sensors, and in particular but not exclusively, relates to image sensors that include event sensing circuitry.

### Background

Image sensors have become ubiquitous and are now widely used in digital cameras, cellular phones, security cameras, as well as medical, automobile, and other applications. As image sensors are integrated into a broader range of electronic devices, it is desirable to enhance their functionality, performance metrics, and the like in as many ways as possible (e.g., resolution, power consumption, dynamic range, etc.) through both device architecture design as well as image acquisition processing.

A typical image sensor operates in response to image light from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bitlines that vary as a function of the incident image light. In other words, the amount of image charge generated is proportional to the intensity of the image light, which is read out as analog image signals from the column bitlines and converted to digital values to provide information that is representative of the external scene.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 illustrates one example of stacked complementary metal oxide semiconductor (CMOS) image sensor (CIS) system in accordance with the teachings of the present invention.

FIG. 2A illustrates one example of a pixel array with an example of a 4C (2×2) Bayer color filter pattern of red (R), green (G), and blue (B) color filters in accordance with the teachings of the present invention.

FIG. 2B illustrates one example of a readout of a pixel array with 4C (2×2) photodiode binning in accordance with the teachings of the present invention.

FIG. 2C illustrates one example of a readout of a pixel array with 2× fast vertical binning and 2× digital horizontal binning of 4C (2×2) photodiode groupings in accordance with the teachings of the present invention.

FIG. 2D illustrates one example of a simultaneous readout of a pixel array with 2× digital horizontal binning of 4C (2×2) photodiode groupings included in the same columns as multiple rows of the pixel array that are read out for event driven sensing in accordance with the teachings of the present invention.

FIG. 3 illustrates one example schematic of a stacked CIS system with a pixel array that can be read out with an image readout circuit and an event driven circuit to simultaneously capture images/video and detect events in accordance with the teachings of the present disclosure.

FIG. 4 illustrates another example schematic of a stacked CIS system with a pixel array that can be read out with an image readout circuit and an event driven circuit to simultaneously capture images/video and detect events in accordance with the teachings of the present disclosure.

FIG. 5 illustrates yet another example schematic of a stacked CIS system with a pixel array that can be read out with an image readout circuit and an event driven circuit to simultaneously capture images/video and detect events in accordance with the teachings of the present disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. In addition, common but well-understood elements that are useful or necessary in a commercially feasible embodiment are often not depicted in order to facilitate a less obstructed view of these various embodiments of the present invention.

### DETAILED DESCRIPTION

Various examples directed to a hybrid optical sensor with simultaneous image/video capturing and event driven sensing capabilities are described herein. In the following description, numerous specific details are set forth to provide a thorough understanding of the examples. One skilled in the relevant art will recognize, however, that the techniques described herein can be practiced without one or more of the specific details, or with other methods, components, materials, etc. In other instances, well-known structures, materials, or operations are not shown or described in detail in order to avoid obscuring certain aspects.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

Spatially relative terms, such as “beneath,” “below,” “over,” “under,” “above,” “upper,” “top,” “bottom,” “left,” “right,” “center,” “middle,” and the like, may be used herein for ease of description to describe one element or feature's relationship relative to another element(s) or feature(s) as illustrated in the figures. It will be understood that the spatially relative terms are intended to encompass different orientations of the device in use or operation in addition to the orientation depicted in the figures. For example, if the device in the figures is rotated or turned over, elements described as “below” or “beneath” or “under” other elements or features would then be oriented “above” the other elements or features. Thus, the exemplary terms “below” and “under” can encompass both an orientation of above and below. The device may be otherwise oriented (rotated ninety degrees or at other orientations) and the spatially relative descriptors used herein are interpreted accordingly. In addition, it will also be understood that when an element is referred to as being “between” two other elements, it can be the only element between the two other elements, or one or more intervening elements may also be present.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

As will be discussed, various examples of stacked CIS system in which a hybrid optical sensor with simultaneous image/video capturing and event driven sensing capabilities are disclosed. Although normal image/video sensors offer great image and/or video capturing capabilities, one of the limitations with normal image/video sensors is that normal image sensors do not provide ultra-high frame rates and ultra-high speed capture capabilities that may be useful in a variety of applications such as machine vision, gaming, and artificial intelligence sensing areas. Attempts to provide typical image/video sensors to with such ultra-high frame rates and ultra-high speed capabilities have resulted in compromised solutions that provide poor quality image captures compared to their normal image sensor counterparts.

In the various examples disclosed herein, a hybrid optical sensor is provided in which the optical sensor includes a combination of a normal image/video sensing that provides great image and video capture capabilities, as well as simultaneously sense events at ultra-high frame rates and at ultra-high speeds from pixel cells in the same columns of the pixel array for a wide variety of event driven applications.

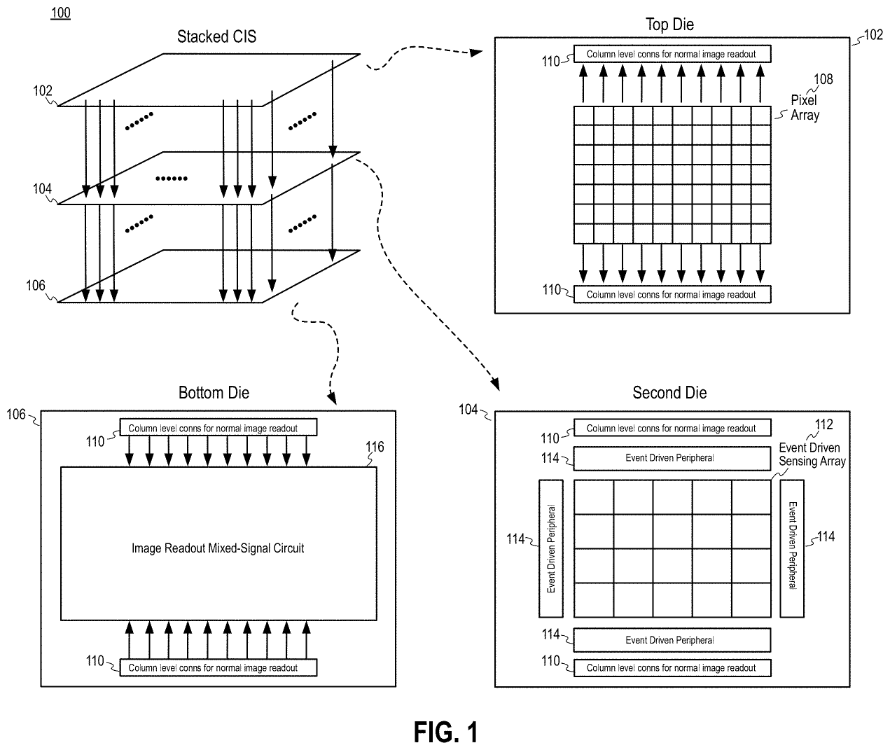

To illustrate, FIG. 1 illustrates one example of stacked complementary metal oxide semiconductor (CMOS) image sensor (CIS) system 100 in accordance with the teachings of the present invention. As shown in the depicted example, stacked CIS system 100 includes a first die 102, a second die, 104, and a third die 106 that are stacked and coupled together in a stacked chip scheme. In various examples, the first die 102, second die 104, and third die 106 are semiconductor dice that include a suitable semiconductor material such as for example silicon. In the example, the first die 102, which may also be referred to as the top die 102 of the stacked CIS 100, includes a pixel array 108. The third die 106, which may also be referred to as the bottom die 106 of the stacked CIS 100, includes an image readout circuit 116, which may also be referred to as image readout mixed-signal circuitry, is coupled to the pixel array 108 of the top die 102 through column level connections for normal image readout 110. In one example, the column level connections for normal image readout 110 may be implemented from column bitlines of the pixel array 108 with through silicon vias (TSVs) between the top die 102 and the bottom die 106, which are routed through the second die 104.

In one example, pixel array 108 is a two-dimensional (2D) array including a plurality of pixel cells that include photodiodes that are exposed to incident light. As will be discussed in greater detail below, in various examples, each of the pixel cells may include a plurality of photodiodes arranged for example in a 4C (2×2) arrangement that share pixel circuitry of the pixel cell. As illustrated in the depicted example, the pixel cells are arranged into rows and columns to acquire image data of a person, place, object, etc., which can then be used to render images and/or video of a person, place, object, etc. In the example, each pixel cell is configured to photogenerate image charge in response to the incident light. After each pixel cell has acquired its image charge, the corresponding analog image charge data is read out by the image readout circuit 116 in the bottom die 106 through column bit lines, which may be implemented with through silicon vias (TSVs) included in the column level connections for normal image readout 110. In the various examples, the image charge from each row of pixel array 108 may be read out in parallel through column bit lines by image readout circuit 116.

In the various examples, the image readout circuit 116 in the bottom die 106 includes amplifiers, analog to digital converter (ADC) circuitry, associated analog support circuitry, associated digital support circuitry, etc., for normal image readout and processing. In some examples, image readout circuit 116 may also include event driven readout circuitry, which will be described in greater detail below. In operation, the photogenerated analog image charge signals are read out from the pixel cells of pixel array 108, amplified, and converted to digital values in image readout circuit 116. In some examples, image readout circuit 116 may readout a row of image data at a time. In other examples, image readout circuit 116 may readout the image data using a variety of other techniques (not illustrated), such as a serial readout or a full parallel readout of all pixels simultaneously. The image data may be stored or even manipulated by applying post image effects (e.g., crop, rotate, remove red eye, adjust brightness, adjust contrast, or otherwise).

In the depicted example, the second die 104, which may also be referred to as the middle die 104 of the stacked CIS 100, includes an event driven sensing array 112 that is coupled to the pixel array 108 in the top die 102. In the various examples, the event driven sensing array 112 is coupled to the pixel cells of pixel array 108 through hybrid bonds between the top die 102 and the middle die 104. In one example, the event driven sensing array 112 includes an array of event driven circuits. As will be discussed, in one example, each one of the event driven circuits in event driven sensing array 112 is coupled to a plurality of pixel cells of the pixel cells in pixel array 108 through hybrid bonds between the top die 102 and the middle die 104 to asynchronously detect events that occur in the light that is incident upon the pixel array 108 in accordance with the teachings of the present invention.

In one example, each one of the event driven circuits in event driven sensing array 112 is coupled to 8 pixel cells included in two rows of the pixel array 108. In the various examples, corresponding event detection signals are generated by the event driven circuits in the event driven sensing array 112. The event detection signals may be coupled to be received and processed by event driven peripheral circuitry 114, which in one example is arranged around the periphery of event driven sensing array 112 in the middle die 104 as shown in FIG. 1. The depicted example also illustrates the column level connections for normal image readout 110 that are routed through middle die 104 between the top die 102 and the bottom die 106.

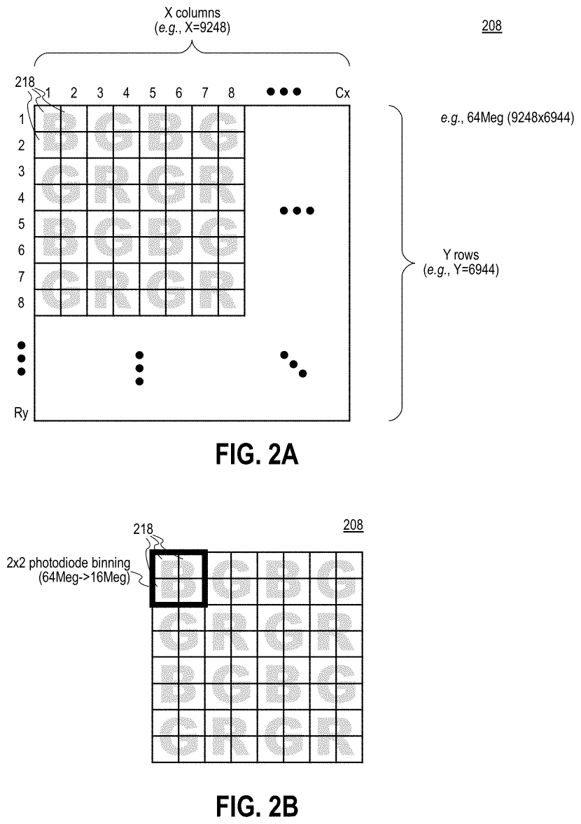

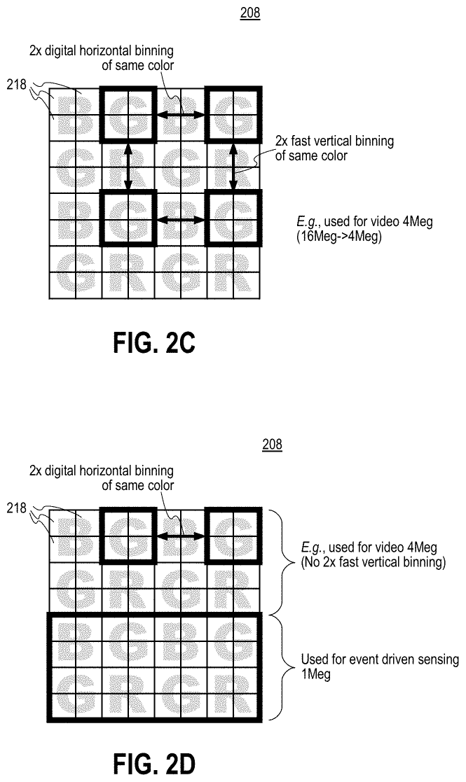

FIG. 2A illustrates one example of a pixel array 208 in accordance with the teachings of the present invention. It is appreciated that the pixel array 208 of FIG. 2A may be an example implementation of pixel array 108 of the example stacked CIS system 100 as shown in FIG. 1, and that similarly named and numbered elements described above are coupled and function similarly below.

As shown in the depicted example, pixel array 208 includes a plurality of photodiodes 218. As illustrated in the depicted example, photodiodes 218 are arranged into rows (e.g., 1, 2, 3, . . . , Ry) and columns (e.g., 1, 2, 3, . . . , Cx). In one example, pixel array 208 is a 64 megapixel array with X=9,248 columns and Y=6,944 rows. In other examples, it is appreciated the pixel array 208 may have different dimensions.

The example depicted in FIG. 2A also illustrates that pixel array 208 is a color pixel array with a Bayer color filter pattern including red (R), green (G), and blue (B) color filters. In the example, Bayer binning is provided with 4C (2×2) groupings of red (R) color filters, 4C (2×2) groupings of green (G) color filters, and 4C (2×2) groupings of blue (B) color filters, which are disposed over respective photodiodes 218. In various examples, it is appreciated that pixel array 208 of FIG. 2A may be utilized for normal image/video capture in a variety of resolutions including for instance full resolution image captures up to 64 megapixels, as well as video formats including 4K, 1080p, 720p, etc.

For instance, FIG. 2B illustrates one example of a readout of a pixel array 208 with 4C (2×2) photodiode binning to capture a 16 megapixel image/video in accordance with the teachings of the present invention. As shown, each 4C (2×2) grouping of photodiodes 218 of the same color (e.g., red (R), green (G), blue (B)) may be read out together with Bayer binning. In particular, the charge information photogenerated from the four photodiodes 218 of each 4C (2×2) grouping of the same color are combined together when read out of the pixel array 208. As will be illustrated below, in one example, the four photodiodes 218 of each 4C (2×2) grouping of photodiodes 218 share a floating diffusion, reset transistor, source follower, and row select transistor of the pixel circuitry of a pixel cell, which are then read out from pixel array 208 to capture a 16 megapixel image/video from pixel array 208.

FIG. 2C illustrates one example of a readout of a pixel array 208 with 2× fast vertical binning and 2× digital horizontal binning of 4C (2×2) photodiode groupings in accordance with the teachings of the present invention. As shown in the depicted example, four 4C (2×2) groupings of photodiodes 218 of the same color (e.g., red (R), green (G), blue (B)) may be read out together with Bayer binning. In the example, 2× fast vertical binning is performed on each pair of 4C (2×2) groupings of photodiodes 218 of the same color that are coupled to the same column bitline to perform the vertical binning. Furthermore, 2× digital horizontal binning is performed on each pair of 4C (2×2) groupings of photodiodes 218 of the same color in the same row. In one example, the 2× digital horizontal binning may be performed after the analog to digital conversion (ADC) is performed in the image readout circuit. With the 2× fast vertical binning and the 2× digital horizontal binning of the four 4C (2×2) groupings of photodiodes 218 of the same color, a 4 megapixel image/video may be captured from pixel array 208.

FIG. 2D illustrates one example of a simultaneous readout of a pixel array with 2× digital horizontal binning of 4C (2×2) photodiode groupings and multiple rows of the pixel array for event driven sensing in accordance with the teachings of the present invention. As shown in the depicted example, 2× digital horizontal binning is performed on a pair of 4C (2×2) groupings of photodiodes 218 of the same color in the same row in a first portion (e.g., the upper 4 rows of photodiodes or upper 2 rows of 4C (2×2) groupings of photodiodes) of the pixel array shown in FIG. 2D.

However, in the depicted example, no 2× fast vertical binning is performed on pairs of 4C (2×2) groupings of photodiodes 218 of the same color that share the same column bitline. Instead, in the depicted example, every 4 rows of photodiodes, or every 2 rows of 4C (2×2) groupings of photodiodes, are disconnected from the image readout circuit. Rather, the plurality of pixel cells in a second portion (e.g., lower 4 rows of photodiodes or lower 2 rows of 4C (2×2) groupings of photodiodes) of the pixel array 208, which are disconnected from the image readout circuit, are read out simultaneously by event driven circuitry for event driven sensing in accordance with the teachings of the present invention. In the lower portion or second portion from which event driven events are detected, the row control buffers are gated (e.g., enabled/disabled) to support this reconfiguration in accordance with the teachings of the present invention.

As will be discussed, in the depicted example, pixel cells that are read out for event driven sensing include pixel cells that are in the same columns as pixel cells that are read out simultaneously by the image readout circuit in accordance with the teachings of the present invention. In the example depicted in FIG. 2D, the second portion of the pixel array 208 that is read out by the event driven circuit for event driven sensing includes two rows or 8 pixel cells. The event driven sensing of the 4C (2×2) groupings of photodiodes from these two rows of the pixel array 208 is equivalent to providing a 1 megapixel sensor for ultra-high frame rate and ultra-high speed event driven sensing in accordance with the teachings of the present invention.

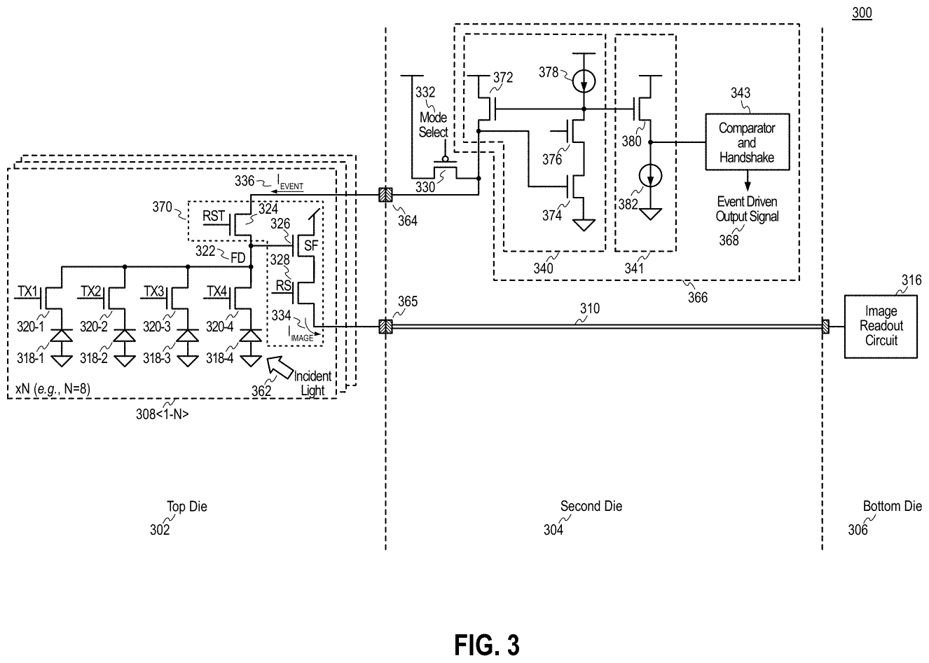

To illustrate, FIG. 3 shows one example schematic of a stacked CIS system 300 with a pixel array including pixel cells 308 that can be read out with an image readout circuit 316 and an event driven circuit 366 to simultaneously capture images/video and detect events from the same column of the pixel array in accordance with the teachings of the present disclosure. It is appreciated the stacked CIS system 300 of FIG. 3 may be one example of the stacked CIS system 100 as shown in FIG. 1, and that similarly named and numbered elements described above are coupled and function similarly below.

In the example depicted in FIG. 3, a grouping of N pixel cells 308<1>-308<N> of the pixel array that are included in top die 302 is illustrated. In one example, the grouping of N pixel cells 308<1>-308<N> shown in FIG. 3 may correspond to the first portion (e.g., upper portion including 4 rows of photodiodes or 2 rows of 4C (2×2) groupings of photodiodes) of the pixel array 208 of FIG. 2D, or the second portion (e.g., lower portion including 4 rows of photodiodes or 2 rows of 4C (2×2) groupings of photodiodes) of the pixel array 208 shown in FIG. 2D above. In the example, N=8 pixel cells 308<1>-308<N> across two rows of 4C (2×2) pixel cells the pixel array 208 of FIG. 2D. It is appreciated that in other examples, N may be equal to a different number.

As shown in the example depicted in FIG. 3, each pixel cell 308<1>-308<N> is a shared pixel design that includes photodiodes 318-1, 318-2, 318-3, 318-4 that are configured to photogenerate charge in response to incident light 362. Thus, in one example, the four photodiodes 318-1, 318-2, 318-3, 318-4 may be arranged as a 4C (2×2) arrangement of photodiodes in a pixel array as shown in FIGS. 2A-2D. In other examples, it is appreciated that a different number of photodiodes may be included.

In the example illustrated in FIG. 3, transfer transistors 320-1, 320-2, 320-3, 320-4 are coupled to the photodiodes 318-1, 318-2, 318-3, 318-4, respectively. A floating diffusion 322 is coupled to the photodiodes 318-1, 318-2, 318-3, 318-4 through transfer transistors 320-1, 320-2, 320-3, 320-4, respectively, to receive the photogenerated charge from photodiodes 318-1, 318-2, 318-3, 318-4. A gate of source follower transistor 326 is coupled to the floating diffusion 322 to generate an image data signal in response to the charge in the floating diffusion 322 that is photogenerated by the photodiodes 318-1, 318-2, 318-3, 318-4. In one example, the image data signal includes a current I_{IMAGE} 334 that is coupled to be read out through a row select transistor 328 and received by image readout circuitry 316 in the bottom die 306 through a hybrid bond 365 from top die 302 to second die 304, which is then routed through a through silicon via (TSV) 310 through the second die 304 to the bottom die 306 as shown.

In the example depicted in FIG. 3, a reset transistor 324 is coupled to floating diffusion 322. In one example, reset transistor 324 is coupled to reset the photogenerated charge in pixel cell 308 in a normal image readout mode. For instance, in one example, reset transistor 324 is coupled to reset the charge in the floating diffusion 322. In one example, reset transistor 324 is also coupled to photodiodes 318-1, 318-2, 318-3, 318-4 through transfer transistors 320-1, 320-2, 320-3, 320-4 to reset the charge in photodiodes 318-1, 318-2, 318-3, 318-4.

It is noted that the drain of the reset transistor 324 is not coupled to a pixel supply voltage in top die 302. Instead, as shown in the illustrated example, the drain of reset transistor 324 in top die 302 is coupled through a hybrid bond 364 to a mode select switch 330 disposed in the second die 304 in accordance with the teachings of the present invention. In the example, the mode select switch 330 is configured when turned ON to couple the drain of the reset transistor 324 to a voltage supply in response to a mode select signal 332.

In one example, the three readout transistors including reset transistor 324, source follower transistor 326, and row select transistor 328 may be isolated from the other devices included in the pixel cell 308 with an isolation structure 370, which may include for example a full deep trench isolation (DTI) structure or the like. In addition, in various examples, each pixel cell 308 is isolated from each adjacent neighboring pixel cell 308 with isolation structures such as full deep trench isolation (DTI) structures or the like.

As mentioned, the pixel cell 308 example illustrated in FIG. 3 is one of the plurality of N pixel cells 308<1>-308<N> that are included in the pixel array. Thus, in one example, when the mode select switch 330 is turned ON in a normal image readout mode, the mode select switch 330 is configured to couple the drain of the reset transistor 324 of each the plurality of N pixel cells 308<1>-308<N> to the voltage supply through one or more hybrid bonds 364 in response to the mode select signal 332 in accordance with the teachings of the present invention.

It is appreciated that when the mode select switch 330 is configured to couple the voltage supply to the drain of the reset transistors 324, the plurality of N pixel cells 308<1>-308<N> are configured to operate in a normal imaging mode. When configured in the normal imaging mode, the image readout circuit 316 can be used to capture images or video from the plurality of N pixel cells 308<1>-308<N> in accordance with the teachings of the present invention. This example is described with respect the first portion (e.g., the upper 4 rows of photodiodes or upper 2 rows of 4C (2×2) pixel cells) of the pixel array 208 in FIG. 2D above from which images or video may be captured from the pixel array 208 by the image readout circuit in accordance with the teachings of the present invention.

Continuing with the example depicted in FIG. 3, when the mode select switch 330 is turned OFF in response to the mode select signal 332, the plurality of N pixel cells 308<1>-308<N> are configured to operate in an event driven sensing mode. This example is described with respect the second portion (e.g., the lower 4 rows of photodiodes or lower 2 rows of 4C (2×2) pixel cells) of the pixel array 208 in FIG. 2D above from which event data signals may be read out from the pixel array 208 through the drain of the reset transistor 324 with an event driven circuit in accordance with the teachings of the present invention.

To illustrate, during the event driven mode, the mode select switch 330 is configured to be turned OFF in response to the mode select signal 332. As such, the voltage supply included in second die 304 is disconnected from the drain of reset transistor 324. Instead, an event driven circuit 366 included in second die 304 is coupled to read out the event data signals, which are included in a photocurrent I_{EVENT} 336 generated by the photodiodes 318-1, 318-2, 318-3, 318-4, through hybrid bonds 364 and the reset transistor 324.

In the example depicted in FIG. 3, the event driven circuit 366 includes a converter circuit 340 coupled to the drain of reset transistor 324 to convert a photocurrent I_{EVENT} 336 of the event data signal to a voltage. The voltage buffer circuit 341 is coupled to the converter circuit 340 to buffer the output voltage signal of the converter circuit 340. A comparator and handshake circuit 343 is coupled to the voltage buffer circuit 341 to generate an event driven output signal 368 in response to the output of the voltage buffer circuit 341.

As shown in the example of FIG. 3, the converter circuit 340 includes a first transistor 372 having a source coupled to the reset transistor 324 through hybrid bond 364. First transistor 372 also includes a drain coupled to the voltage supply. A second transistor 374 has a gate coupled to the source of the first transistor 372 and the drain of the reset transistor through the hybrid bond 364. The second transistor also has a source coupled to ground. A third transistor 376 has a drain coupled to a gate of the first transistor 372 and a first current source 378. Third transistor 376 also has a source coupled to a drain of the second transistor 374. In the depicted example, the voltage buffer circuit 341 includes a fourth transistor 380 having a gate coupled to the drain of the third transistor 376 and the gate of the first transistor 372. The fourth transistor 380 also includes a source coupled to a second current source 382.

In operation, the transfer transistors 320-1, 320-2, 320-3, 320-4 and the reset transistor 324 are switched ON and row select transistor 328 is switched OFF during the event driven mode. As such, incident light 362 that is incident on photodiodes 318-1, 318-2, 318-3, 318-4 photogenerates charge, which results in a photocurrent I_{EVENT} 336 that flows through photodiodes 318-1, 318-2, 318-3, 318-4, transfer transistors 320-1, 320-2, 320-3, 320-4, reset transistor 324, and event driven circuitry 366 during the event driven mode. If the external scene is static and thus there is no event occurring, the brightness of incident light 362 remains unchanged. As such, the photocurrent I_{EVENT} 336 generated by photodiode 318-1, 318-2, 318-3, 318-4 remains substantially constant. However, if an event occurs (e.g., movement, etc.) in the external scene, the event is indicated with an asynchronous change in the brightness of incident light 362. As such, there is an asynchronous change or delta in the photocurrent I_{EVENT} 336 generated by photodiodes 318-1, 318-2, 318-3, 318-4. Changes in the photocurrent I_{EVENT} 336 are detected by the event driven circuit 366 as event data, which is indicated in the event driven output signal 368 generated by the comparator and handshake circuit 343 in accordance with the teachings of the present invention.

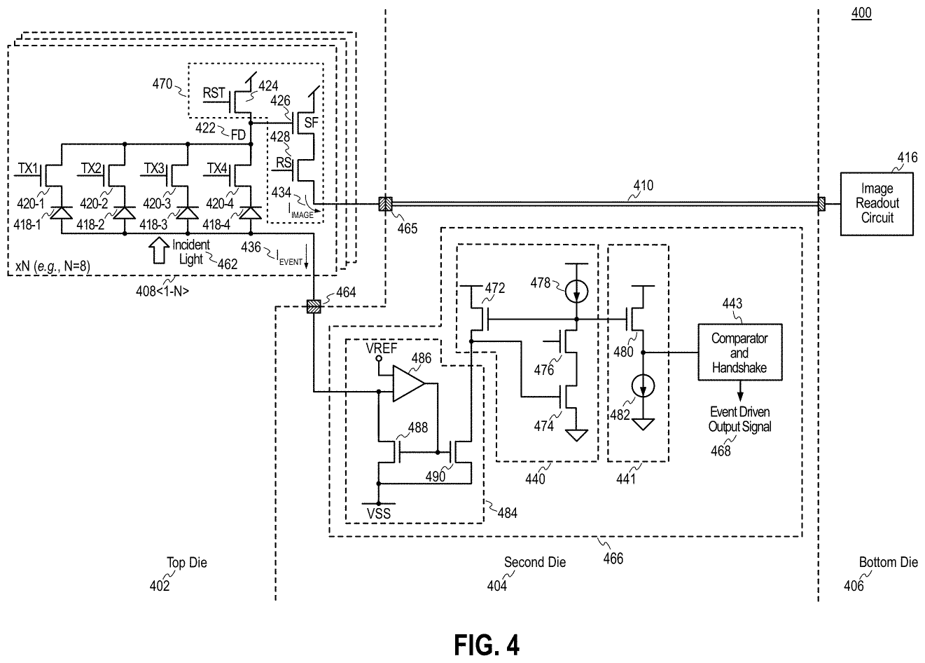

FIG. 4 illustrates another example schematic of a stacked CIS system 400 with a pixel array including pixel cells 408 that can be read out with an image readout circuit 416 and an event driven circuit 466 to simultaneously capture images/video and detect events from the same column of the pixel array in accordance with the teachings of the present disclosure. It is appreciated the stacked CIS system 400 of FIG. 4 may be another example of the stacked CIS system 300 as shown in FIG. 3, or of stacked CIS system 100 as shown in FIG. 1, and that similarly named and numbered elements described above are coupled and function similarly below.

It is appreciated the stacked CIS system 400 of FIG. 4 shares many similarities with the stacked CIS system 300 as shown in FIG. 3. For instance, as shown in the example depicted in FIG. 4, a grouping of N pixel cells 408<1>-408<N> of the pixel array that are included in top die 402 is illustrated. In one example, the grouping of N pixel cells 408<1>-408<N> shown in FIG. 4 may also correspond to the first portion (e.g., upper portion including 4 rows of photodiodes or 2 rows of 4C (2×2) groupings of photodiodes) of the pixel array 208 of FIG. 2D, or the second portion (e.g., lower portion including 4 rows of photodiodes or 2 rows of 4C (2×2) groupings of photodiodes) of the pixel array 208 shown in FIG. 2D above. In the example, N=8 pixel cells 408<1>-408<N> across two rows of 4C (2×2) pixel cells the pixel array 208 of FIG. 2D. It is appreciated that in other examples, N may be equal to a different number.

As shown in the example depicted in FIG. 4, each pixel cell 408<1>-408<N> is a shared pixel design that includes photodiodes 418-1, 418-2, 418-3, 418-4 that are configured to photogenerate charge in response to incident light 462. Thus, in one example, the four photodiodes 418-1, 418-2, 418-3, 418-4 may be arranged as a 4C (2×2) arrangement of photodiodes in a pixel array as shown in FIGS. 2A-2D. In other examples, it is appreciated that a different number of photodiodes may be included.

In the example illustrated in FIG. 4, transfer transistors 420-1, 420-2, 420-3, 420-4 are coupled to the photodiodes 418-1, 418-2, 418-3, 418-4, respectively. A floating diffusion 422 is coupled to the photodiodes 418-1, 418-2, 418-3, 418-4 through transfer transistors 420-1, 420-2, 420-3, 420-4, respectively, to receive the photogenerated charge from photodiodes 418-1, 418-2, 418-3, 418-4. A gate of source follower transistor 426 is coupled to the floating diffusion 422 to generate an image data signal in response to the charge in the floating diffusion 422 that is photogenerated by the photodiodes 418-1, 418-2, 418-3, 418-4. In one example, the image data signal includes a current I_{IMAGE} 434 that is coupled to be read out through a row select transistor 428 and received by image readout circuitry 416 in the bottom die 406 through a hybrid bond 465 from top die 402 to second die 404, which is then routed through a through silicon via (TSV) 410 through the second die 404 to the bottom die 406 as shown.

In the example depicted in FIG. 4, a reset transistor 424 is coupled to floating diffusion 422. One of the differences between the stacked CIS system 400 of FIG. 4 and the stacked CIS system 300 as shown in FIG. 3 is that in the stacked CIS system 400 of FIG. 4, the drain of reset transistor 424 is also coupled to a supply voltage in top die 402 to reset the photogenerated charge in pixel cell 408 in a normal image readout mode. For instance, in the example, reset transistor 424 is coupled to reset the charge in the floating diffusion 422. In one example, reset transistor 424 is also coupled to photodiodes 418-1, 418-2, 418-3, 418-4 through transfer transistors 420-1, 420-2, 420-3, 420-4 to reset the charge in photodiodes 418-1, 418-2, 418-3, 418-4.

In one example, the three readout transistors including reset transistor 424, source follower transistor 426, and row select transistor 428 are isolated from the other devices included in the pixel cell 408 with an isolation structure 470, which may include for example a full deep trench isolation (DTI) structure or the like. As such, the p doped regions of the photodiodes 418-1, 418-2, 418-3, 418-4 as well as the transfer transistors 420-1, 420-2, 420-3, 420-4 of the first die 402 are isolated from the reset transistor 424, source follower transistor 426, and row select transistor 428. In addition, in various examples, each pixel cell 408 is isolated from each adjacent neighboring pixel cell 408 with isolation structures such as full deep trench isolation (DTI) structures or the like.

In various examples, the three readout transistors including reset transistor 424, source follower transistor 426, and row select transistor 428 may also be formed by devices that have native isolated body contact such as for example fin field effect transistors (FinFETs), gate-all-around (nanowire) FETs, silicon-on-insulator (SOI) FETs, transistors integrated into the back-end-of-line (BEOL) transistors such as for example Indium-Gallium-Zinc-Oxide (IGZO) transistors, or transistors integrated on a separate wafer, by means of three dimensional 3D integration via hybrid bonds or through silicon via (TSV) technologies, or other suitable structures that provide suitable isolation to isolate the pixel cells 408 and associated currents from neighboring pixel cells.

Continuing with the example depicted in FIG. 4, event data may be read out from each pixel cell 408<1>-408<N> by event driven circuit 466 in second die 404 through hybrid bonds 464 when configured to operate in an event driven sensing mode. This example is described with respect the second portion (e.g., the lower 4 rows of photodiodes or lower 2 rows of 4C (2×2) pixel cells) of the pixel array 208 in FIG. 2D above from which event data signals may be read out from the pixel array 208 with an event driven circuit in accordance with the teachings of the present invention.

In the example depicted in FIG. 4, the event driven circuit 466 includes a current amplifier 484 having an input coupled to an anode of each one of the plurality of photodiodes 418-1, 418-2, 418-3, 418-4 to receive a photocurrent I_{EVENT} 436 of the event data signal from the plurality of photodiodes 418-1, 418-2, 418-3, 418-4. In one example, the anode of each one of the plurality of photodiodes 418-1, 418-2, 418-3, 418-4 is in a p doped region of the first die 402 in which the pixel cells 408 are disposed. A converter circuit 440 is coupled to the current amplifier 484 to convert an output of the current amplifier 484 to a voltage. A voltage buffer circuit 441 is coupled to the converter circuit 440 to buffer an output of the converter circuit 440. A comparator and handshake circuit 443 is coupled to the voltage buffer circuit 441 to generate an event driven output signal in response to an output of the voltage buffer circuit 441 to generate an event driven output signal 468 in response to the output of the voltage buffer circuit 441.

In the depicted example, the converter circuit 440 includes a first transistor 472 having a source coupled to the output of the current amplifier 484. The first transistor 472 also includes a drain coupled to a voltage supply. A second transistor 474 includes a gate coupled to the source of the first transistor 472 and the output of the current amplifier 484. The second transistor 474 also includes a source coupled to ground. A third transistor 476 includes a drain coupled to a gate of the first transistor 472 and a first current source 478. Third transistor 476 also includes a source coupled to a drain of the second transistor 474. The voltage buffer circuit 441 includes a fourth transistor 480 that includes a gate coupled to the drain of the third transistor 476 and the gate of the first transistor 472. The fourth transistor 480 also includes a source that is coupled to a second current source 482.

Continuing with the example depicted in FIG. 4, the current amplifier 484 includes a fifth transistor 488 having a drain that is coupled to the anode of each one of the plurality of photodiodes 418-1, 418-2, 418-3, 418-4 through hybrid bonds 464 to receive the photocurrent I_{EVENT} 436 of the event data signal from the plurality of photodiodes 418-1, 418-2, 418-3, 418-4. Fifth transistor 488 also includes a source coupled to a VSS voltage reference. In various examples, the VSS voltage reference may be a suitable voltage reference value such as for example ground (e.g., zero volts), a positive voltage, or a negative voltage. A sixth transistor 490 includes a gate that is coupled to a gate of the fifth transistor 488. The sixth transistor 490 also includes a source coupled to the VSS voltage reference. The sixth transistor 490 further includes a drain that is coupled to the output of the current amplifier 484.

A first opamp 486 includes a first input that is coupled to a reference voltage. In one example, the reference voltage is substantially equal to ground. The first opamp 486 also includes a second input that is coupled to the drain of the fifth transistor 488 and the anode of each one of the plurality of photodiodes 418-1, 418-2, 418-3, 418-4 through hybrid bonds 464. The first opamp 486 further includes an output that is coupled to gate of the fifth transistor and the gate of the sixth transistor. During operation, the voltage difference between the first and second inputs of opamp 486 is small. As such, when the reference voltage coupled to the first input of opamp 486 is substantially equal to ground, the second input of opamp 486 is substantially equal to ground such that the anodes of the plurality of photodiodes 418-1, 418-2, 418-3, 418-4 are, in effect, coupled to a virtual ground provided by the second input of opamp 486.

In operation, the incident light 462 that is incident on photodiodes 418-1, 418-2, 418-3, 418-4 photogenerates charge, which results in a photocurrent I_{EVENT} 436 that flows through photodiodes 418-1, 418-2, 418-3, 418-4 and event driven circuitry 466 during the event driven mode. In the depicted example, photocurrent I_{EVENT} 436 is a hole current that is generated at the anodes of photodiodes 418-1, 418-2, 418-3, 418-4 in response to the incident light 462 from the external scene. If the external scene is static and thus there is no event occurring, the brightness of incident light 462 remains unchanged. As such, the photocurrent I_{EVENT} 436 generated by photodiodes 418-1, 418-2, 418-3, 418-4 remains constant. However, if an event occurs (e.g., movement, etc.) in the external scene, the event is indicated with an asynchronous change in the brightness of incident light 462. As such, there is an asynchronous change or delta in the photocurrent I_{EVENT} 436 generated by photodiodes 418-1, 418-2, 418-3, 418-4. Changes in the photocurrent I_{EVENT} 436 are detected by the event driven circuit 466 as event data, which is indicated in the event driven output signal 468 generated by the comparator and handshake circuit 443 in accordance with the teachings of the present invention.

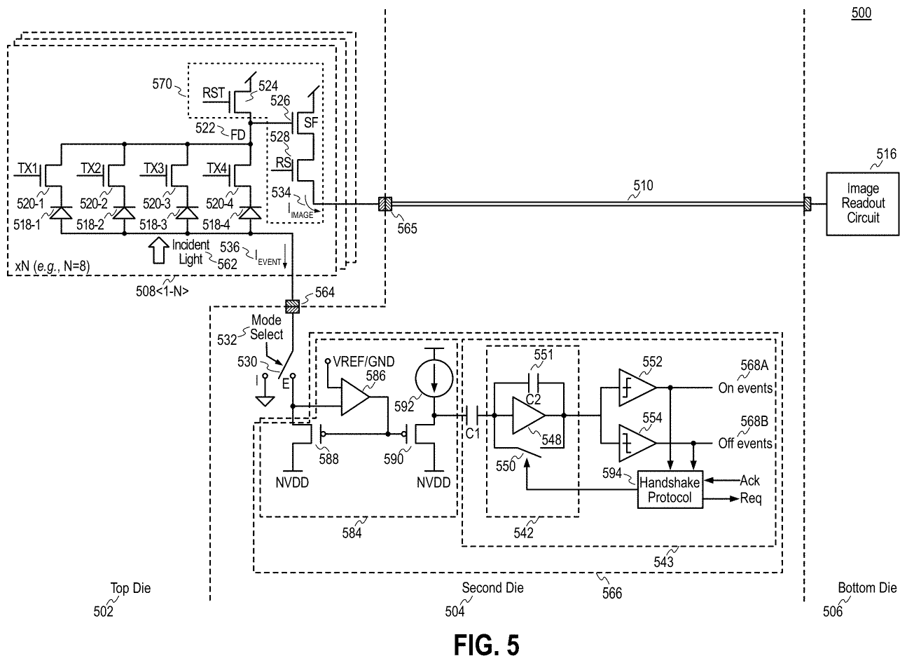

FIG. 5 illustrates yet another example schematic of a stacked CIS system 500 with a pixel array 508 that can be read out with an image readout circuit 516 and an event driven circuit 566 to simultaneously capture images/video and detect events from the same column in accordance with the teachings of the present disclosure. It is appreciated the stacked CIS system 500 of FIG. 5 may be another example of the stacked CIS system 400 as shown in FIG. 4, or of stacked CIS system 300 as shown in FIG. 3, or of stacked CIS system 100 as shown in FIG. 1, and that similarly named and numbered elements described above are coupled and function similarly below.

It is appreciated the stacked CIS system 500 of FIG. 5 shares many similarities with the stacked CIS system 400 as shown in FIG. 4. For instance, as shown in the example depicted in FIG. 5, a grouping of N pixel cells 508<1>-508<N> of the pixel array that are included in top die 502 is illustrated. In one example, the grouping of N pixel cells 508<1>-508<N> shown in FIG. 5 may also correspond to the first portion (e.g., upper portion including 4 rows of photodiodes or 2 rows of 4C (2×2) groupings of photodiodes) of the pixel array 208 of FIG. 2D, or the second portion (e.g., lower portion including 4 rows of photodiodes or 2 rows of 4C (2×2) groupings of photodiodes) of the pixel array 208 shown in FIG. 2D above. In the example, N=8 pixel cells 508<1>-508<N> across two rows of 4C (2×2) pixel cells the pixel array 208 of FIG. 2D. It is appreciated that in other examples, N may be equal to a different number.

As shown in the example depicted in FIG. 5, each pixel cell 508<1>-508<N> is a shared pixel design that includes photodiodes 518-1, 518-2, 518-3, 518-4 that are configured to photogenerate charge in response to incident light 562. Thus, in one example, the four photodiodes 518-1, 518-2, 518-3, 518-4 may be arranged as a 4C (2×2) arrangement of photodiodes in a pixel array as shown in FIGS. 2A-2D. In other examples, it is appreciated that a different number of photodiodes may be included.

In the example illustrated in FIG. 5, transfer transistors 520-1, 520-2, 520-3, 520-4 are coupled to the photodiodes 518-1, 518-2, 518-3, 518-4, respectively. A floating diffusion 522 is coupled to the photodiodes 518-1, 518-2, 518-3, 518-4 through transfer transistors 520-1, 520-2, 520-3, 520-4, respectively, to receive the photogenerated charge from photodiodes 518-1, 518-2, 518-3, 518-4. A gate of source follower transistor 526 is coupled to the floating diffusion 522 to generate an image data signal in response to the charge in the floating diffusion 522 that is photogenerated by the photodiodes 518-1, 518-2, 518-3, 518-4. In one example, the image data signal includes a current I_{IMAGE} 534 that is coupled to be read out through a row select transistor 528 and received by image readout circuitry 516 in the bottom die 506 through a hybrid bond 565 from top die 502 to second die 504, which is then routed through a through silicon via (TSV) 510 through the second die 504 to the bottom die 506 as shown.

In the example depicted in FIG. 5, a reset transistor 524 is coupled to floating diffusion 522 and also to a supply voltage in top die 502 to reset the photogenerated charge in pixel cell 508 in a normal image readout mode. For instance, in the example, reset transistor 524 is coupled to reset the charge in the floating diffusion 522. In one example, reset transistor 524 is also coupled to photodiodes 518-1, 518-2, 518-3, 518-4 through transfer transistors 520-1, 520-2, 520-3, 520-4 to reset the charge in photodiodes 518-1, 518-2, 518-3, 518-4.

In one example, the three readout transistors including reset transistor 524, source follower transistor 526, and row select transistor 528 are isolated from the other devices included in the pixel cell 508 with an isolation structure 570, which may include for example a full deep trench isolation (DTI) structure or the like. As such, the p doped regions of the photodiodes 518-1, 518-2, 518-3, 518-4 as well as the transfer transistors 520-1, 520-2, 520-3, 520-4 of the first die 502 are isolated from the reset transistor 524, source follower transistor 526, and row select transistor 528. In addition, in various examples, each pixel cell 508 is isolated from each adjacent neighboring pixel cell 508 with isolation structures such as full deep trench isolation (DTI) structures or the like.

In various examples, the three readout transistors including reset transistor 524, source follower transistor 526, and row select transistor 528 may also be formed by devices that have native isolated body contact such as for example fin field effect transistors (FinFETs), gate-all-around (nanowire) FETs, silicon-on-insulator (SOI) FETs, transistors integrated into the back-end-of-line (BEOL) transistors such as for example Indium-Gallium-Zinc-Oxide (IGZO) transistors, or transistors integrated on a separate wafer, by means of three dimensional 3D integration via hybrid bonds or through silicon via (TSV) technologies, or other suitable structures that provide suitable isolation to isolate the pixel cells 508 and associated currents from neighboring pixel cells.

Continuing with the example depicted in FIG. 5, event data may be read out from each pixel cell 508<1>-508<N> by event driven circuit 566 in second die 504 through hybrid bonds 564 when configured to operate in an event driven sensing mode. This example is described with respect the second portion (e.g., the lower 4 rows of photodiodes or lower 2 rows of 4C (2×2) pixel cells) of the pixel array 208 in FIG. 2D above from which event data signals may be read out from the pixel array 208 with an event driven circuit in accordance with the teachings of the present invention.

In the example depicted in FIG. 5, the event driven circuit 566 includes a current amplifier 584 having an input coupled to an anode of each one of the plurality of photodiodes 518-1, 518-2, 518-3, 518-4 through hybrid bonds 564 to receive a photocurrent I_{EVENT} 536 of the event data signal from the plurality of photodiodes 518-1, 518-2, 518-3, 518-4 in response to the incident light 562 from the incident scene. In one example, the anode of each one of the plurality of photodiodes 518-1, 518-2, 518-3, 518-4 is p doped region of the first die 502 in which pixel cells 508 are disposed. An integrator 542 is coupled to the current amplifier 584 to integrate an output of the current amplifier 584. It is appreciated that the example integrator 542 illustrated in FIG. 5 is a design example provided for explanation purposes, and may perform additional suitable functions such as for example but not limited to filtering, amplification, etc. A comparator and handshake circuit 543, which includes the integrator 542 in the example depicted in FIG. 5, is configured to generate an event driven output signal 568, which in the depicted example includes an On events signal 568A and an Off events signal 568B, in response to an output of the integrator 542.

In the example depicted in FIG. 5, an optional mode select switch 530 is also included in second die 504 as shown. In the example, the mode select switch is coupled to the anode of each one of the plurality of photodiodes 518-1, 518-2, 518-3, 518-4 through hybrid bonds 564, the input of the current amplifier 584 through a node “E”, and ground through a node “I.” In the example illustrated in FIG. 5, the “E” label represents an event driven sensing mode and the “I” label represents a normal imaging mode for stacked CIS system 500. In operation, the optional mode select switch 530 is configured to couple of the anode of each one the plurality of photodiodes 518-1, 518-2, 518-3, 518-4 either to ground or to the input of the current amplifier 584. As will be discussed, in an example in which optional mode select switch 530 is not included, the plurality of photodiodes 518-1, 518-2, 518-3, 518-4 are coupled to a virtual ground provided by a second input of opamp 586 of current amplifier 584.

As shown in the example of FIG. 5, the current amplifier 584 includes a fifth transistor 588 that includes a source to be coupled to the anode of each one of the plurality of photodiodes 518-1, 518-2, 518-3, 518-4 to receive the photocurrent I_{EVENT} 536 of the event data signal from the plurality of photodiodes 518-1, 518-2, 518-3, 518-4 generated in response to the incident light 562 from the external scene. The fifth transistor 588 also includes a drain coupled to a voltage supply NVDD. A sixth transistor 590 includes a gate that is coupled to a gate of the fifth transistor 588. The sixth transistor 590 also includes a drain coupled to the voltage supply NVDD. The sixth transistor further includes a source that is coupled to a third current source 592 and the output of the current amplifier 584. In the depicted example, the fifth transistor 588 and the sixth transistor 590 are PMOS transistors.

As shown in the depicted example, a first opamp 586 is also included, which includes a first input that is coupled to a reference voltage. In one example, the reference voltage is substantially equal to ground. The first opamp 586 also includes a second input that is coupled to the drain of the fifth transistor 588 and the anode of each one of the plurality of photodiodes 518-1, 518-2, 518-3, 518-4. The first opamp 586 further includes an output that is coupled to the gate of the fifth transistor 588 and the gate of the sixth transistor 590. During operation, the voltage difference between the first and second inputs of opamp 586 is small. As such, when the reference voltage coupled to the first input of opamp 586 is substantially equal to ground, the second input of opamp 586 is substantially equal to ground such that the anodes of the plurality of photodiodes 518-1, 518-2, 518-3, 518-4 are, in effect, coupled to a virtual ground provided by the second input of opamp 586.

In the example illustrated in FIG. 5, the integrator 542 includes a second opamp 548 including an input that is capacitively coupled through a capacitor C1 to the output of the current amplifier 584. The integrator 542 also includes a capacitor C2 that is coupled between the input of second opamp 548 and an output of second opamp 548. A reset switch 550 is also coupled between the input of second opamp 548 and an output of second opamp 548.

As shown in the depicted example, the comparator and handshake circuit 543 also includes a first threshold detection circuit 552 that is coupled to the output of the second opamp 548 to generate a first threshold detection output signal 568A in response to the output of the second opamp 548. The first threshold detection output signal 568A is labeled “On events” in FIG. 5. The comparator and handshake circuit 543 also includes a second threshold detection circuit 554 that is coupled to the output of the second opamp 548 to generate a second threshold detection output signal 568B in response to the output of the second opamp 548. The second threshold detection output signal 568B is labeled “Off events” in FIG. 5. In the illustrated example, it is appreciated that the first and second threshold detection output signals 568A and 568B provide an event driven output signal of the comparator and handshake circuit 543.

In the depicted example, the comparator and handshake circuit 543 also includes a handshake protocol circuit 594 that is coupled to the first threshold detection circuit 552 and the second threshold detection circuit 554 to control switching of the reset switch 550 in response to the first threshold detection output signal 568A and the second threshold detection output signal 568B. In the depicted example, the handshake protocol circuit 594 is further configured to receive an acknowledge signal (Ack) and generate a request signal (Req) as shown.

In operation, the incident light 562 that is incident on photodiodes 518-1, 518-2, 518-3, 518-4 photogenerates charge, which results in a photocurrent I_{EVENT} 536 that flows through photodiodes 518-1, 518-2, 518-3, 518-4 and event driven circuitry 566 during the event driven mode. In the depicted example, photocurrent I_{EVENT} 536 is a hole current that is generated at the anodes of photodiodes 518-1, 518-2, 518-3, 518-4 in response to incident light 562 from the external scene. If the external scene is static and thus there is no event occurring, the brightness of incident light 562 remains unchanged. As such, the photocurrent I_{EVENT} 536 generated by photodiodes 518-1, 518-2, 518-3, 518-4 remains constant. However, if an event occurs (e.g., movement, etc.) in the external scene, the event is indicated with an asynchronous change in the brightness of incident light 562. As such, there is an asynchronous change or delta in the photocurrent I_{EVENT} 536 generated by photodiodes 518-1, 518-2, 518-3, 518-4. Changes in the photocurrent I_{EVENT} 536 are detected by the event driven circuit 566 as event data, which is indicated in the first threshold detection output signal 568A and the second threshold detection output signal 568B generated by the comparator and handshake circuit 543 in accordance with the teachings of the present invention.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

1. An optical sensor, comprising:
a plurality of pixel cells arranged into rows and columns of a pixel array, wherein each of the pixel cells comprises:
a plurality of photodiodes configured to photogenerate charge in response to incident light; and
a source follower transistor configured to generate an image data signal in response to the charge photogenerated from the plurality of photodiodes;
an image readout circuit coupled to the plurality of pixel cells to read out the image data signal generated from the source follower transistor of at least a first one of the plurality of pixel cells of a first row of the pixel array; and
an event driven circuit coupled to the plurality of pixel cells to read out the event data signals generated in response to the charge photogenerated from the plurality of photodiodes of a second row of the plurality of pixel cells of the pixel array,
wherein the image readout circuit is coupled to read out the image data signal and the event driven circuit is coupled to read out the event data signals from pixel array simultaneously.

2. The optical sensor of claim 1,
wherein the columns of the pixel array include a first column of pixel cells,
wherein the first column of pixel cells includes said at least the first one of the plurality of pixel cells of the first row of the pixel array from which the image data signal is read out by the image readout circuit, and
wherein the first column of pixel cells further includes one of the plurality of pixel cells of the second row of the pixel array from which the event data signals are read out simultaneously by the event driven circuit.

3. The optical sensor of claim 2, wherein the second row of the pixel array from which the event data signals are read out simultaneously by the event driven circuit is one of a plurality of rows of the pixel array from which the event data signals are read out simultaneously by the event driven circuit.

4. The optical sensor of claim 3, wherein the plurality of rows of the pixel array from which the event driven circuit is coupled to read out event data signals simultaneously includes eight pixel cells.

5. The optical sensor of claim 1, wherein the pixel array is included in a first die, wherein the event driven circuit is included in a second die, wherein the image readout circuit is included in a third die, wherein the first die, the second die, and the third die stacked together to form a stacked complementary metal oxide semiconductor (CMOS) image sensor (CIS).

6. The optical sensor of claim 1, wherein each of the pixel cells further comprises:
a plurality of transfer transistors coupled to the plurality of photodiodes;
a floating diffusion coupled to the plurality of transfer transistors, wherein the source follower transistor is configured to generate the image data signal in response to the charge transferred from the plurality of photodiodes to the floating diffusion through the plurality of transfer transistors;
a reset transistor coupled to the floating diffusion; and
a row select transistor coupled between the source follower transistor and the image readout circuit, wherein the readout circuit is configured to read out the image data signal generated from the source follower transistor through the row select transistor.

7. The optical sensor of claim 6, further comprising a mode select switch coupled between the reset transistor and a voltage supply,
wherein the mode select switch configured to couple the reset transistor to the voltage supply in response to a mode select signal, and
wherein the event driven circuit is coupled to the reset transistor to read out the event data signals through the reset transistor.

8. The optical sensor of claim 7, wherein the event driven circuit comprises:
a converter circuit coupled to the reset transistor to convert a photocurrent of the event data signal to a voltage;
a voltage buffer circuit coupled to the converter circuit to buffer an output of the converter circuit; and
a comparator and handshake circuit coupled to the voltage buffer circuit to generate an event driven output signal in response to an output of the voltage buffer circuit.

9. The optical sensor of claim 8, wherein the converter circuit comprises:
a first transistor having a source coupled to the reset transistor, and a drain coupled to the voltage supply;
a second transistor having a gate coupled to the source of the first transistor and the reset transistor, and a source coupled to ground; and
a third transistor having a drain coupled to a gate of the first transistor and a first current source, and a source coupled to a drain of the second transistor.

10. The optical sensor of claim 9, wherein the voltage buffer circuit comprises a fourth transistor having a gate coupled to the drain of the third transistor and the gate of the first transistor, and a source coupled to a second current source.

11. The optical sensor of claim 6, wherein the event driven circuit comprises:
a current amplifier having an input coupled to an anode of each one of the plurality of photodiodes to receive a photocurrent of the event data signal from the plurality of photodiodes;
a converter circuit coupled to the current amplifier to convert an output of the current amplifier to a voltage;
a voltage buffer circuit coupled to the converter circuit to buffer an output of the converter circuit; and
a comparator and handshake circuit coupled to the voltage buffer circuit to generate an event driven output signal in response to an output of the voltage buffer circuit.

12. The optical sensor of claim 11, wherein the converter circuit comprises:
a first transistor having a source coupled to the output of the current amplifier, and a drain coupled to a voltage supply;
a second transistor having a gate coupled to the source of the first transistor and the output of the current amplifier, and a source coupled to ground; and
a third transistor having a drain coupled to a gate of the first transistor and a first current source, and a source coupled to a drain of the second transistor.

13. The optical sensor of claim 12, wherein the voltage buffer circuit comprises a fourth transistor having a gate coupled to the drain of the third transistor and the gate of the first transistor, and a source coupled to a second current source.

14. The optical sensor of claim 13, wherein the current amplifier comprises:
a fifth transistor having a drain coupled to the anode of each one of the plurality of photodiodes to receive the photocurrent of the event data signal from the plurality of photodiodes, and a source coupled to a voltage reference;
a sixth transistor having a gate coupled to a gate of the fifth transistor, a source coupled to the voltage reference, and a drain coupled to the output of the current amplifier; and
a first opamp having a first input coupled to a reference voltage, a second input coupled to the drain of the fifth transistor and the anode of each one of the plurality of photodiodes, and an output coupled to gate of the fifth transistor and the gate of the sixth transistor.

15. The optical sensor of claim 6, wherein the event driven circuit comprises:
a current amplifier having an input coupled to an anode of each one of the plurality of photodiodes to receive a photocurrent of the event data signal from the plurality of photodiodes;
an integrator coupled to the current amplifier to integrate an output of the current amplifier; and
a comparator and handshake circuit coupled to the integrator to generate an event driven output signal in response to an output of the integrator.

16. The optical sensor of claim 15, wherein the event driven circuit further comprises a mode select switch coupled to the anode of each one of the plurality of photodiodes, the input of the current amplifier, and ground,
wherein the mode select switch is configured to couple of the anode of each one the plurality of photodiodes to one of ground or the input of the current amplifier.

17. The optical sensor of claim 15, wherein the current amplifier comprises:
a fifth transistor having a source coupled to the anode of each one of the plurality of photodiodes to receive the photocurrent of the event data signal from the plurality of photodiodes, and a drain coupled to a voltage supply;
a sixth transistor having a gate coupled to a gate of the fifth transistor, a drain coupled to the voltage supply, and a source coupled to a third current source and the output of the current amplifier; and
a first opamp having a first input coupled to a reference voltage, a second input coupled to the drain of the fifth transistor and the anode of each one of the plurality of photodiodes, and an output coupled to the gate of the fifth transistor and the gate of the sixth transistor.

18. The optical sensor of claim 17, wherein the integrator comprises:
a second opamp having an input capacitively coupled to the output of the current amplifier;
a capacitor coupled between the input of the second opamp and an output of the second opamp; and
a reset switch coupled between the input of the second opamp and the output of the second opamp.

19. The optical sensor of claim 18, wherein the comparator and handshake circuit comprises:
a first threshold detection circuit coupled to the second opamp to generate a first threshold detection output signal in response to the output of the second opamp;
a second threshold detection circuit coupled to the second opamp to generate a second threshold detection output signal in response to the output of the second opamp; and
a handshake protocol circuit coupled to the first threshold detection circuit and the second threshold detection circuit to control switching of the reset switch in response to the first threshold detection output signal and the second threshold detection output signal, wherein the event driven output signal comprises the first threshold detection output signal and the second threshold detection output signal.

20. The optical sensor of claim 6, wherein the anode of each one of the plurality of photodiodes is disposed in a p-doped region of a first die in which the pixel cells are disposed.

21. The optical sensor of claim 20, wherein a photocurrent of the event data signal from the plurality of photodiodes read out by the event driven circuit comprises a hole current.

22. The optical sensor of claim 6, wherein the pixel cells are isolated from one another with a full deep trench isolation (DTI) structure surrounding each of the pixel cells in a first die in which the pixel cells are disposed.

23. The optical sensor of claim 6, wherein the reset transistor, the source follower transistor, and row select transistor are isolated from the plurality of photodiodes and the plurality of transfer transistors with a full deep trench isolation (DTI) structure disposed in a first die in which the pixel cells are disposed.

24. The optical sensor of claim 23, wherein the reset transistor, the source follower transistor, and row select transistor are comprised of fin field effect transistors (FinFETs).

25. A stacked complementary metal oxide semiconductor (CMOS) image sensor (CIS) system, comprising:
a first die including a pixel array including a plurality of pixel cells arranged in rows and columns, wherein each of the pixel cells comprises:
a plurality of photodiodes configured to photogenerate charge in response to incident light; and
a source follower transistor configured to generate an image data signal in response to the charge photogenerated from the plurality of photodiodes;
a second die stacked with the first die, wherein the second die comprises an event driven circuit coupled to the plurality of pixel cells to read out the event data signals generated in response to the charge photogenerated from the plurality of photodiodes of a second row of the plurality of pixel cells of the pixel array; and
a third die stacked with the first die and the second die, wherein the second die is disposed between the first die and the third die, wherein the third die comprises an image readout circuit coupled to the plurality of pixel cells to read out the image data signal generated from the source follower transistor of at least a first one of the plurality of pixel cells of a first row of the pixel array,
wherein the image readout circuit is coupled to read out the image data signal and the event driven circuit is coupled to read out the event data signals from pixel array simultaneously.

26. The stacked CIS system of claim 25,
wherein the columns of the pixel array include a first column of pixel cells,
wherein the first column of pixel cells includes said at least the first one of the plurality of pixel cells of the first row of the pixel array from which the image data signal is read out by the image readout circuit, and
wherein the first column of pixel cells further includes one of the plurality of pixel cells of the second row of the pixel array from which the event data signals are read out simultaneously by the event driven circuit.

27. The stacked CIS system of claim 26, wherein the second row of the pixel array from which the event data signals are read out simultaneously by the event driven circuit is one of a plurality of rows of the pixel array from which the event data signals are read out simultaneously by the event driven circuit.

28. The stacked CIS system of claim 27, wherein the the plurality of rows of the pixel array from which the event driven circuit is coupled to read out event data signals simultaneously includes eight pixel cells.

29. The stacked CIS system of claim 25, wherein each of the pixel cells further comprises:
a plurality of transfer transistors coupled to the plurality of photodiodes;
a floating diffusion coupled to the plurality of transfer transistors, wherein the source follower transistor is configured to generate the image data signal in response to the charge transferred from the plurality of photodiodes to the floating diffusion through the plurality of transfer transistors;
a reset transistor coupled to the floating diffusion; and
a row select transistor coupled between the source follower transistor and the image readout circuit, wherein the readout circuit is configured to read out the image data signal generated from the source follower transistor through the row select transistor.

30. The stacked CIS system of claim 25, further comprising a mode select switch disposed in the second die and coupled between the reset transistor and a voltage supply,
wherein the mode select switch configured to couple the reset transistor to the voltage supply in response to a mode select signal, and
wherein the event driven circuit is coupled to the reset transistor to read out the event data signals through the reset transistor.

31. The stacked CIS system of claim 30, wherein the event driven circuit comprises:
a converter circuit coupled to the reset transistor to convert a photocurrent of the event data signal to a voltage;
a voltage buffer circuit coupled to the converter circuit to buffer an output of the converter circuit; and
a comparator and handshake circuit coupled to the voltage buffer circuit to generate an event driven output signal in response to an output of the voltage buffer circuit.

32. The stacked CIS system of claim 31, wherein the converter circuit comprises:
a first transistor having a source coupled to the reset transistor, and a drain coupled to the voltage supply;
a second transistor having a gate coupled to the source of the first transistor and the reset transistor, and a source coupled to ground; and
a third transistor having a drain coupled to a gate of the first transistor and a first current source, and a source coupled to a drain of the second transistor.

33. The stacked CIS system of claim 32, wherein the voltage buffer circuit comprises a fourth transistor having a gate coupled to the drain of the third transistor and the gate of the first transistor, and a source coupled to a second current source.

34. The stacked CIS system of claim 29, wherein the event driven circuit comprises:
a current amplifier having an input coupled to an anode of each one of the plurality of photodiodes to receive a photocurrent of the event data signal from the plurality of photodiodes;
a converter circuit coupled to the current amplifier to convert an output of the current amplifier to a voltage;
a voltage buffer circuit coupled to the converter circuit to buffer an output of the converter circuit; and
a comparator and handshake circuit coupled to the voltage buffer circuit to generate an event driven output signal in response to an output of the voltage buffer circuit.

35. The stacked CIS system of claim 34, wherein the converter circuit comprises:
a first transistor having a source coupled to the output of the current amplifier, and a drain coupled to a voltage supply;
a second transistor having a gate coupled to the source of the first transistor and the output of the current amplifier, and a source coupled to ground; and
a third transistor having a drain coupled to a gate of the first transistor and a first current source, and a source coupled to a drain of the second transistor.

36. The stacked CIS system of claim 35, wherein the voltage buffer circuit comprises a fourth transistor having a gate coupled to the drain of the third transistor and the gate of the first transistor, and a source coupled to a second current source.

37. The stacked CIS system of claim 36, wherein the current amplifier comprises:
a fifth transistor having a drain coupled to the anode of each one of the plurality of photodiodes to receive the photocurrent of the event data signal from the plurality of photodiodes, and a source coupled to a voltage reference;
a sixth transistor having a gate coupled to a gate of the fifth transistor, a source coupled to the voltage reference, and a drain coupled to the output of the current amplifier; and
a first opamp having a first input coupled to a reference voltage, a second input coupled to the drain of the fifth transistor and the anode of each one of the plurality of photodiodes, and an output coupled to gate of the fifth transistor and the gate of the sixth transistor.

38. The stacked CIS system of claim 29, wherein the event driven circuit comprises:
a current amplifier having an input coupled to an anode of each one of the plurality of photodiodes to receive a photocurrent of the event data signal from the plurality of photodiodes;
an integrator coupled to the current amplifier to integrate an output of the current amplifier; and
a comparator and handshake circuit coupled to the integrator to generate an event driven output signal in response to an output of the integrator.

39. The stacked CIS system of claim 38, further comprising a mode select switch disposed in the second die and coupled to the anode of each one of the plurality of photodiodes, the input of the current amplifier, and ground,
wherein the mode select switch is configured to couple of the anode of each one the plurality of photodiodes to one of ground or the input of the current amplifier.

40. The stacked CIS system of claim 38, wherein the current amplifier comprises:
a fifth transistor having a source coupled to the anode of each one of the plurality of photodiodes to receive the photocurrent of the event data signal from the plurality of photodiodes, and a drain coupled to a voltage supply;
a sixth transistor having a gate coupled to a gate of the fifth transistor, a drain coupled to the voltage supply, and a source coupled to a third current source and the output of the current amplifier; and
a first opamp having a first input coupled to a reference voltage, a second input coupled to the drain of the fifth transistor and the anode of each one of the plurality of photodiodes, and an output coupled to the gate of the fifth transistor and the gate of the sixth transistor.

41. The stacked CIS system of claim 40, wherein the integrator comprises:
a second opamp having an input capacitively coupled to the output of the current amplifier;
a capacitor coupled between the input of the second opamp and an output of the second opamp; and
a reset switch coupled between the input of the second opamp and the output of the second opamp.

42. The stacked CIS system of claim 41, wherein the comparator and handshake circuit comprises:
a first threshold detection circuit coupled to the second opamp to generate a first threshold detection output signal in response to the output of the second opamp;
a second threshold detection circuit coupled to the second opamp to generate a second threshold detection output signal in response to the output of the second opamp; and
a handshake protocol circuit coupled to the first threshold detection circuit and the second threshold detection circuit to control switching of the reset switch in response to the first threshold detection output signal and the second threshold detection output signal, wherein the event driven output signal comprises the first threshold detection output signal and the second threshold detection output signal.

43. The stacked CIS system of claim 29, wherein the anode of each one of the plurality of photodiodes is disposed in a p-doped region of the first die.

44. The stacked CIS system of claim 43, wherein a photocurrent of the event data signal from the plurality of photodiodes read out by the event driven circuit comprises a hole current.

45. The stacked CIS system of claim 29, wherein the pixel cells are isolated from one another with a full deep trench isolation (DTI) structure surrounding each of the pixel cells in the first die.

46. The stacked CIS system of claim 29, wherein the reset transistor, the source follower transistor, and row select transistor are isolated from the plurality of photodiodes and the plurality of transfer transistors with a full deep trench isolation (DTI) structure disposed in the first die.

47. The stacked CIS system of claim 46, wherein the reset transistor, the source follower transistor, and row select transistor are comprised of fin field effect transistors (FinFETs).
